(19) United States
(12) Patent Application Publication
(10) Pub. No.: US 2016/0237566 A1
(43) Pub. Date: Aug. 18, 2016

(54) FILM FORMING DEVICE AND FILM FORMING METHOD

(71) Applicant: MITSUI ENGINEERING & SHIPBUILDING CO., LTD., Tokyo (JP)

(72) Inventors: Nozomu HATTORI, Tamano-shi, Okayama (JP); Naomasa MIYATAKE, Tamano-shi, Okayama (JP); Yasunari MORI, Tamano-shi, Okayama (JP); Yoshiharu NAKASHIMA, Tamano-shi, Okayama (JP)

(21) Appl. No.: 15/025,807

(22) PCT Filed: Mar. 13, 2014
(86) PCT No.: PCT/JP2014/056622

§ 371 Date: Mar. 29, 2016

(30) Foreign Application Priority Data
Oct. 16, 2013 (JP) 2013-215437

(51) Int. Cl. C23C 16/455; C23C 16/50

(52) U.S. Cl. CPC C23C 16/45527; C23C 16/50; C23C 16/45536

(57) ABSTRACT

When a film is formed atomic layer by atomic layer with a use of a raw material gas and a reaction gas, a raw material gas is supplied into a film-forming space in which a substrate is placed to adsorb a component of the raw material gas onto the substrate. Then, a reaction gas is supplied into the film-forming space. Plasma is produced in the film-forming space using the reaction gas supplied so that part of a component of the raw material gas adsorbed on the substrate reacts with the reaction gas. At this moment, a duration of production of the plasma is set within a range of 0.5 millisecond to 100 milliseconds according to a degree of at least one property of a film to be formed, and a density of power input to the plasma source is in a range of 0.05 W/cm² to 10 W/cm².

### TECHNICAL FIELD

The present invention relates to a film-forming device and a film-forming method for forming a film atomic layer by atomic layer with the use of a raw material gas and a reaction gas.

### BACKGROUND ART

Nowadays, a film-forming method is known in which a thin film is formed atomic layer by atomic layer by ALD (Atomic Layer Deposition). Such ALD is performed by alternately supplying a raw material gas and a reaction gas as precursor gases onto a substrate so that a thin film is formed which has a structure in which atomic layer films are stacked on top of one another. Such a thin film obtained by ALD can have a very small thickness of about 0.1 nm, and therefore the film-forming method based on ALD is effectively used for producing various devices as a high-precision film-forming method.

For example, an ALD film-forming method using plasma is known in which oxygen radicals are formed by activating a reaction gas such as oxygen gas that reacts with a raw material gas with the use of plasma, and then the oxygen radicals are reacted with a component of the raw material gas adsorbed on a substrate (Patent Literature 1). Further, an ALD film-forming method not using plasma is also known in which a gas such as ozone that reacts with a raw material gas is reacted with a component of the raw material gas adsorbed on a substrate (Patent Literature 2).

### CITATION LIST

### Patent Literatures

Patent Literature 1: JP 2011-181681 A

Patent Literature 2: JP 2009-209434 A

### SUMMARY OF INVENTION

### Technical Problem

Among these ALD film-forming methods, the method using plasma can form a dense film due to the activation of a reaction gas. However, the use of plasma sometimes damages a substrate surface or a film due to the bombardment of the substrate surface with ions in plasma. On the other hand, when a highly-active gas such as ozone or water is used without using plasma, such damage to a substrate surface or a film caused by using plasma can be prevented, but it is more difficult to form a dense film as compared to when plasma is used.

It is therefore an object of the present invention to provide a film-forming device and a film-forming method by which a film ranging from a dense film to a less-dense film can be freely formed on a substrate by plasma ALD with little damage to the surface of the substrate or the film.

Means to solve the Problem

An aspect of the invention is a film-forming device for forming a film atomic layer by atomic layer with a use of a raw material gas and a reaction gas.

### Embodiment 1

The film-forming device includes:
a film-forming vessel having a film-forming space in which a substrate is placed;
a raw material gas supply part configured to supply a raw material gas into the film-forming space to adsorb a component of the raw material gas onto the substrate;
a reaction gas supply part configured to supply a reaction gas into the film-forming space;
a plasma source that includes an electrode configured to produce plasma using the reaction gas supplied into the film-forming space so that a film is formed on the substrate by a reaction between part of the component of the raw material gas adsorbed on the substrate and the reaction gas; and
a high-frequency power source configured to supply power to the electrode of the plasma source so that a duration of production of the plasma is in a range of 0.5 millisecond to 100 milliseconds and a density of the power input to the plasma source is in a range of 0.05 W/cm² to 10 W/cm², the duration of production of the plasma being set according to a degree of at least one property of a film to be formed selected from refractive index, dielectric strength, and dielectric constant.

### Embodiment 2

The film-forming device according to embodiment 1, further including a first control part configured to determine, as a start point of production of the plasma, a time point when reflected power of power input to the plasma source crosses a value set within a range of 85 to 95% of the input power after the power is input.

### Embodiment 3

The film-forming device according to embodiment 1 or 2, wherein the duration of production of the plasma includes a reaction time from start to end of a reaction between part of the component of the raw material gas and the reaction gas and a property-adjusting time for changing the property of a film formed by the reaction.

### Embodiment 4

The film-forming device according to any one of embodiments 1 to 3, further including a second control part configured to control operations of the raw material gas supply part and the reaction gas supply part to repeat a cycle including supply of a raw material gas performed by the raw material gas supply part, supply of a reaction gas performed by the reaction gas supply part after the supply of the raw material gas, and plasma production using the reaction gas performed by the plasma source, wherein
during repetition of the cycle, the first control part is configured to change the duration of production of the plasma by the plasma source between at least two cycles.

### Embodiment 5

The film-forming device according to embodiment 4, wherein the duration of production of the plasma of a first one cycle is shorter than the duration of production of the plasma of a last one cycle.

### Embodiment 6

The film-forming device according to embodiment 5, wherein the duration of production of the plasma increases as a number of repetitions of the cycle increases.

### Embodiment 7

The film-forming device according to any one of embodiments 4 to 6, wherein production of the plasma is performed more than once in at least one cycle, and a total duration of plasma production performed more than once is in a range of 0.5 millisecond to 100 milliseconds.

### Embodiment 8

The film-forming device according to any one of embodiments 1 to 7, wherein the degree of the property has at least three different levels of the property.

Another aspect of the invention is a film-forming method for forming a film atomic layer by atomic layer with a use of a raw material gas and a reaction gas.

### Embodiment 9

A film-forming method includes the steps of:
supplying a raw material gas into a film-forming space in which a substrate is placed to adsorb a component of the raw material gas onto the substrate;
supplying a reaction gas into the film-forming space; and
supplying power to an electrode of a plasma source to produce plasma in the film-forming space with a use of the reaction gas supplied into the film-forming space so that part of a component of the raw material gas adsorbed on the substrate reacts with the reaction gas to form a film on the substrate, a duration of production of the plasma being set within a range of 0.5 millisecond to 100 milliseconds according to a degree of at least one property of a film to be formed selected from refractive index, dielectric strength, and dielectric constant, and a density of power input to the plasma source being in a range of 0.05 W/cm² to 10 W/cm².

### Embodiment 10

The film-forming method according to embodiment 9, wherein a time point when reflected power of power input to the plasma source to produce the plasma crosses a value set within a range of 85 to 95% of the input power after the power is input is determined as a start point of production of the plasma to determine an end point of input of the power to the plasma source.

### Embodiment 11

The film-forming method according to embodiment 9 or 10, wherein the duration of production of the plasma includes a reaction time from start to end of a reaction between part of the component of the raw material gas and the reaction gas and a property-adjusting time for changing the property of a film formed by the reaction.

### Embodiment 12

The film-forming method according to any one of embodiments 9 to 11, wherein a cycle including supply of the raw material gas, supply of the reaction gas performed after the supply of the raw material gas, and plasma production using the reaction gas performed by the plasma source is repeated, and
during repetition of the cycle, the duration of production of the plasma by the plasma source is different between at least two cycles.

### Embodiment 13

The film-forming method according to embodiment 12, wherein during repetition of the cycle, the duration of production of the plasma of a first one cycle is shorter than the duration of production of the plasma of a last one cycle.

### Embodiment 14

The film-forming method according to embodiment 13, wherein during repetition of the cycle, the duration of production of the plasma increases as a number of repetitions of the cycle increases.

### Embodiment 15

The film-forming method according to embodiment 15, wherein the film has a refractive index increasing from its substrate side to its uppermost layer side.

### Embodiment 16

The film-forming method according to any one of embodiments 12 to 15, wherein production of the plasma is performed more than once in at least one cycle, and a total duration of plasma production performed more than once is in a range of 0.5 millisecond to 100 milliseconds.

### Embodiment 17

The film-forming method according to any one of embodiments 9 to 16, wherein the degree of the property has at least three different levels of the property.

### Embodiment 18

The film-forming method according to any one of embodiments 9 to 17, wherein the substrate is a flexible substrate.

### Embodiment 19

The film-forming method according to any one of embodiments 9 to 18, wherein the film contains a metal component, and the substrate is a plate having a composition not containing the metal component.

### Advantageous Effects of Invention

The above film-forming device and film-forming method make it possible to freely form a film ranging from a dense film to a less-dense film with little damage to the surface of a substrate or the film.

### BRIEF DESCRIPTION OF DRAWINGS

FIG. 1 is a schematic diagram illustrating the structure of an ALD device as one example of a film-forming device according to an embodiment of the present invention.

FIG. 2 is a graph schematically illustrating the time course of reflected power with respect to power input to a plasma source, which is obtained by a controller in the embodiment of the present invention.

FIG. 3 is a graph illustrating an example of a change in the property of a formed film with respect to the duration of plasma production.

FIG. 4 is a graph illustrating one example of a temporal change in the emission intensity of hydrogen radicals detected by a photo-detection sensor during plasma production.

FIG. 5 is a graph illustrating a change in the interface state density Dit of the film formed on a substrate in the example illustrated in FIG. 3 with respect to the duration of plasma production.

### DESCRIPTION OF EMBODIMENTS

Hereinbelow, a film-forming method and a film-forming device according to the present invention will be described in detail.

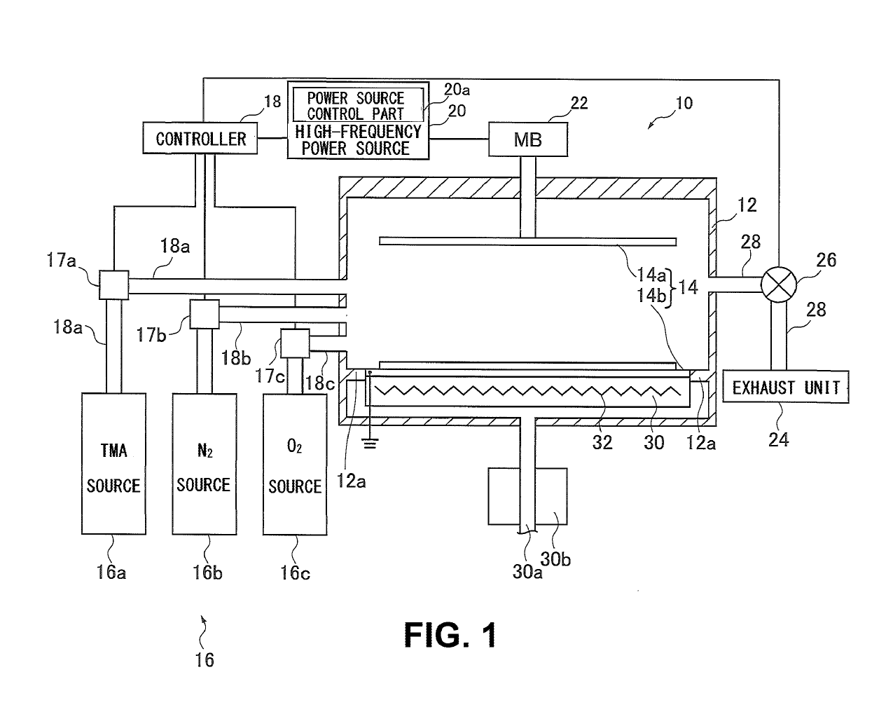

FIG. 1 is a schematic diagram illustrating the structure of an ALD device 10 as one example of a film-forming device according to an embodiment of the present invention. The ALD device 10 illustrated in FIG. 1 alternately supplies a raw material gas that constitutes a film to be formed, such as an organic metal raw material gas containing a metal as a component, and a reaction gas onto a substrate in a film-forming space based on an ALD method.

When supplied into the film-forming space, the raw material gas is adsorbed onto the substrate so that an atomic layer of a certain component of the raw material gas is uniformly formed. When the reaction gas is supplied into the film-forming space, the ALD device 10 allows an electrode as a plasma source to produce plasma using the reaction gas to form radicals of a component of the reaction gas to enhance reaction activity. The radicals are reacted with the component of the raw material gas on the substrate to form a film in atomic layer unit. The ALD device 10 forms a film having a predetermined thickness by repeating the above process as one cycle. At this time, the duration of plasma production per cycle is in the range of 0.5 millisecond to 100 milliseconds. Further, the density of power input to the plasma source is in the range of 0.05 W/cm² to 10 W/cm². Here, the density of power input to the plasma source is a value obtained by dividing input power by the area of a plasma-producing region. The area of a plasma-producing region is the cross-sectional area of a plasma-producing region taken along a plane parallel to the substrate. When the plasma source is a parallel plate electrode 14, the density of power input to the plasma source is almost equal to a value obtained by dividing input power by the area of an upper electrode 14a. This makes it possible to freely form a film ranging from a dense film to a less-dense film with little damage to the surface of the substrate or the film. Particularly, in a case where a dense film is to be formed, the duration of plasma production is set to be long within the above range, and in a case where a less-dense film is to be formed, the duration of plasma production is set to be short within the above range. It is to be noted that a dense film and a less-dense film are different in properties, and therefore the duration of plasma production is set according to preset information about the property (at least one property selected from refractive index, dielectric strength, and dielectric constant) of a film to be formed, for example, according to the degree of refractive index of a film to be formed. The degree of the property preferably has, for example, at least three different levels of the property.

At this time, the duration of plasma production preferably includes a reaction time from the start to the end of a reaction between part of a component of the raw material gas and the reaction gas and a property-adjusting time for changing the value of the property of a film formed by the reaction. Particularly, the property of the film can be changed by changing the property-adjusting time.

The following description will be made with reference to a case where an aluminium oxide film is formed on a substrate with the use of TMA (Trimethyl Aluminium) containing an organic metal as a raw material gas and oxygen gas as a reaction gas.

The ALD device 10 according to this embodiment is a capacitively-coupled plasma-producing device using a parallel plate electrode as a plasma source. However, the structure of a plasma source to be used is not particularly limited, and another plasma-producing device may also be used, such as an electromagnetically-coupled plasma-producing device using two or more antenna electrodes, an ECR plasma-producing device utilizing electron cyclotron resonance, or an inductively-coupled plasma-producing device.

ALD Device

The ALD device 10 includes a film-forming vessel 12, a parallel plate electrode 14, a gas supply unit 16, a controller (first control part, second control part) 18, a high-frequency power source 20, a matching box 22, and an exhaust unit 24.

The film-forming vessel 12 maintains a constant reduced-pressure atmosphere created in its film-forming space by exhaustion through the exhaust unit 24.

In the film-forming space, the parallel plate electrode 14 is provided. The parallel plate electrode 14 has an upper electrode 14a and a lower electrode 14b as electrode plates, and is provided in the film-forming space to produce plasma. The upper electrode 14a of the parallel plate electrode 14 is provided so as to face the substrate-placing surface of a susceptor 30 provided in the film-forming space. On the substrate-placing surface, a substrate is to be placed. That is, a substrate is to be placed in the film-forming space. The upper electrode 14a is connected to the high-frequency power source 20 through the matching box 22 by a power feeder extending from above the film-forming vessel 12. The matching box 22 has an inductor and a capacitor therein, and adjusts the inductance of the inductor and the capacitance of the capacitor for matching to the impedance of the parallel plate electrode 14 at the time of plasma production. The high-frequency power source 20 supplies a high-frequency pulsed power of 13.56 to 27.12 MHz to the upper electrode 14a for a short period of time of 100 milliseconds or shorter.

The surface of the lower electrode 14b acts as a substrate-placing surface and is grounded. The susceptor 30 has a heater 32 therein. During film formation, a substrate is heated by the heater 32 so as to be maintained at, for example, 50° C. or higher but 400° C. or lower.

The susceptor 30 is configured so that an elevating shaft 30a provided at the bottom of the susceptor 30 is freely moved in a vertical direction in FIG. 1 by an elevating system 30b. During film formation, the susceptor 30 is moved to an upper position so that its substrate-placing surface is flush with the upper surface of a projecting wall 12a provided in the film-forming vessel 12. Before or after film formation, the susceptor 30 is moved to a lower position, and a shutter (not illustrated) provided in the film-forming vessel 12 is opened to introduce a substrate into the film-forming vessel 12 from the outside or to take out a substrate from the film-forming vessel 12 to the outside.

The gas supply unit 16 introduces, into the film-forming space, a raw material gas containing an organic metal, a first gas that does not chemically react with the raw material gas, and a second gas that oxidizes a metal component of the organic metal.

Specifically, the gas supply unit 16 has a TMA source 16a, an N₂ source 16b, an O₂ source 16c, valves 17a, 17b, and 17c, a pipe 18a that connects the TMA source 16a and the film-forming space in the film-forming vessel 12 through the valve 17a, a pipe 18b that connects the N₂ source 16b and the film-forming space in the film-forming vessel 12 through the valve 17b, and a pipe 18c that connects the O₂ source 16c and the film-forming space in the film-forming vessel 12 through the valve 17c. The TMA source 16a, the valve 17a, and the pipe 18a constitute a raw material gas supply part. The O₂ source 16c, the valve 17c, and the pipe 18c constitute a reaction gas supply part.

The valves 17a, 17b, and 17c are activated under the control of the controller 18 to introduce TMA as a raw material gas, N₂ gas, and O₂ gas into the film-forming space at predetermined timings, respectively.

The exhaust unit 24 exhausts the raw material gas, the nitrogen gas, and the oxygen gas, introduced into the film-forming space through the left wall of the film-forming vessel 12, from the film-forming space through an exhaust pipe 28 in a horizontal direction. At some point in the exhaust pipe 28, a conductance variable valve 26 is provided. The conductance variable valve 26 is adjusted under instructions from the controller 18.

The controller 18 controls the timing of supply of each of the raw material gas, the nitrogen gas, and the oxygen gas and the timing of supply of power to the parallel plate electrode 14. Further, the controller 18 controls the opening and closing of the valve 26.

Specifically, concurrently with the supply of oxygen gas into the film-forming space, the controller 18 sends a trigger signal to the high-frequency power source 20 to control the start of power supply to the upper electrode 14a of the parallel plate electrode 14 so that the parallel plate electrode 14 produces plasma using oxygen gas.

When a film is to be formed on a substrate, the controller 18 first controls the flow rate of the valve 17a to introduce TMA gas into the film-forming space in which the substrate is placed on the substrate-placing surface. By controlling the flow rate, TMA gas is supplied into the film-forming space for, for example, 0.1 seconds. During the supply of TMA gas into the film-forming space, the exhaust unit 24 always exhausts gas from the film-forming space. That is, when TMA gas is supplied into the film-forming space, part of the TMA gas is adsorbed onto the substrate in the film-forming space, but the remaining unnecessary TMA gas is exhausted from the film-forming space.

Then, the controller 18 stops the supply of TMA into the film-forming space through the valve 17a, and then controls the supply of oxygen gas through the valve 17c to start the supply of oxygen gas into the film-forming space. The supply of oxygen gas into the film-forming space is performed for, for example, 1 second. The controller 18 sends a trigger signal to the high-frequency power source 20 to instruct the high-frequency power source 20 to start the supply of power to the upper electrode 14a through the matching box 22 for a certain period of time during the supply of oxygen gas. The high-frequency power source 20 includes a power source control part 20a that controls the start of power supply according to the trigger signal. The power source control part 20a adjusts a power supply time so that the duration of plasma production becomes, for example, 0.01 seconds. More specifically, information about the property (at least one property selected from refractive index, dielectric strength, and dielectric constant) of a film to be formed, for example, the degree of refractive index is previously set and input to the high-frequency power source 20 by an operator or the like, and the time set within the range of 0.5 millisecond to 100 milliseconds according to the preset information is defined as the duration of plasma production. The information about the property, for example, the magnitude of refractive index preferably has, for example, at least three different refractive index levels. The controller 18 determines the start point of plasma production (as the first control part) so that the actual time during which plasma is continuously produced is in close agreement with the set duration of plasma production. The high-frequency power source 20 counts time to stop the input of power at the end point of plasma production that is the time point when the set duration of plasma production has elapsed after the start point of plasma production determined by the controller 18. It is to be noted that in this embodiment, the controller 18 determines the start point of plasma production (as the first control part), but the power source control part 20a may determine the start point of plasma production (as the first control part). The count and the stop of power input by the high-frequency power source 20 are performed by the power source control part 20a.

The input of power to the upper electrode 14a allows the parallel plate electrode 14 to produce plasma using oxygen gas in the film-forming space. During the supply of oxygen gas into the film-forming space, the exhaust unit 24 always exhausts gas from the film-forming space. More specifically, when oxygen gas is supplied into the film-forming space, part of the oxygen gas is activated by plasma, oxygen radicals produced by the activation react with part of a component of TMA adsorbed on the substrate placed in the film-forming space, and the remaining unnecessary oxygen gas, oxygen radicals produced by plasma, and oxygen ions are exhausted from the film-forming space.

Then, the supply of power to the upper electrode 14a is stopped, and the supply of oxygen gas into the film-forming space through the valve 17c is stopped. Then, the controller 18 again controls the flow rate by the valve 17a so that TMA gas is supplied into the film-forming space. By repeating such a cycle including the supply of TMA gas into the film-forming space, the supply of oxygen gas into the film-forming space, and the production of plasma using oxygen gas, an aluminium oxide film having a predetermined thickness can be formed on the substrate.

It is to be noted that the supply of nitrogen gas from the nitrogen gas source 16b into the film-forming space may always be performed or may sometimes be stopped during each of the periods of TMA gas supply, oxygen gas supply, and plasma production. Nitrogen gas functions as a carrier gas or a purge gas. An inert gas, such as argon gas, may be used instead of nitrogen gas.

Oxygen gas may also be used instead of nitrogen gas as long as a reaction with the raw material gas does not occur.

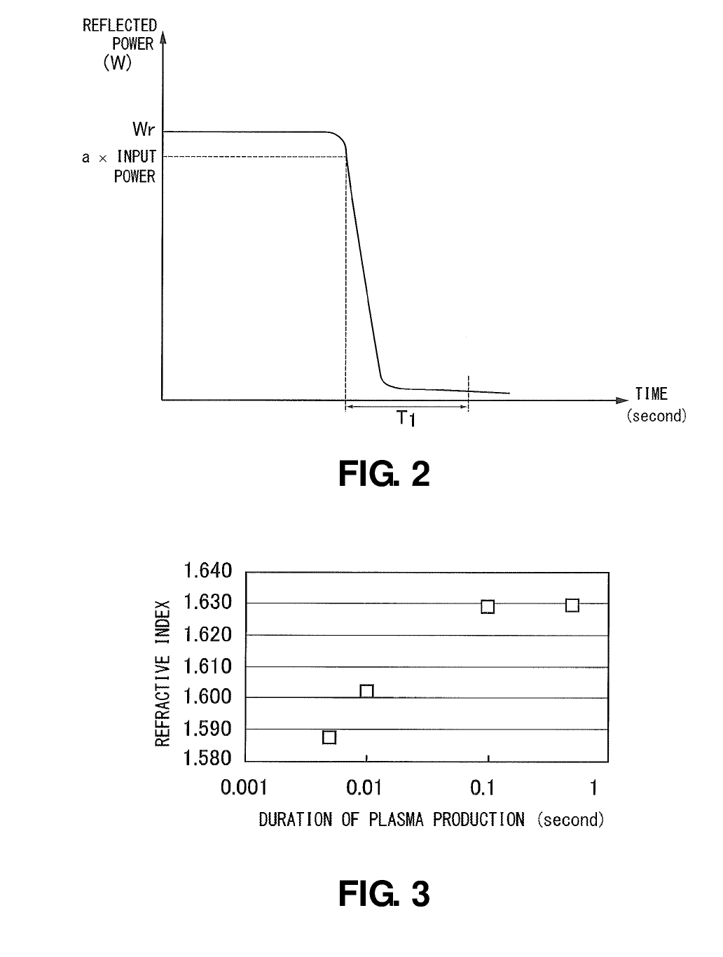

FIG. 2 is a graph schematically illustrating the time course of reflected power with respect to power input to the plasma source, which is obtained by the high-frequency power source 20 in this embodiment. The high-frequency power source 20 is configured so that the power source control part 20a can acquire the data of reflected power at the upper electrode 14a. The reflected power is used by the high-frequency power source 20 to determine the start point of plasma production. In a case where the controller 18 determines the start point of plasma production, the data of reflected power acquired by the high-frequency power source is sent to the controller 18 to allow the controller 18 to make a determination. In a case where the power source control part 20a determines the start point of plasma production, the data of reflected power acquired by the high-frequency power source need not be sent to the controller 18. Therefore, determination of the start point of plasma production by the power source control part 20a makes it possible to eliminate time delay caused by signal processing time or transmission time at the time when the start point of plasma production is determined.

The matching box 22 is adjusted so that impedance matching is established when plasma is produced in the film-forming space. Even when impedance matching is adjusted, plasma is not instantaneously produced at the time when power is supplied to the upper electrode 14a as a plasma source. The time from the start point of power input to the time point when plasma is produced varies. This is because even when conditions where plasma is likely to be produced can be created by placing a voltage between the upper electrode 14a and the lower electrode 14b, the nucleus of electric discharge that produces plasma needs to be produced. The nucleus is produced by various causes, and the time point when the nucleus is produced varies by several hundred milliseconds. In the present embodiment, the duration of plasma production T₁ is short as illustrated in FIG. 2, and therefore the time point when plasma production is started needs to be accurately determined. For this reason, the time point when reflected power Wr of power input to the upper electrode plate 14a as a plasma source is reduced due to plasma production after the input of the power and crosses a value determined by multiplying the input power by a predetermined ratio α (α is a decimal fraction larger than 0 but less than 1) is defined as the start point of plasma production. The ratio cc is preferably set within the range of 0.85 to 0.95. The time point when the reflected power crosses α×input power is defined as the start point of plasma production. The power source control part 20a preferably uses the start point to determine the end point of power input based on the set duration of plasma production T₁. Plasma disappears at the same time as the end of power input. Setting the ratio a within the range of 0.85 to 0.95 makes it possible to reliably determine the start of plasma production without error and to achieve a close agreement between the actual time during which plasma is continuously produced and the set duration of plasma production T₁. If the ratio a is less than 0.85, the determination as to whether plasma has been produced can be made without error, but the actual time during which plasma is continuously produced greatly differs from the set duration of plasma production T₁. For example, a difference in the start point between when the ratio α is 0.85 and when the ratio a is 0.4 is about 1 millisecond. Such a difference in the start point is too large for the set duration of plasma production T₁ to ignore. Therefore, the ratio a is preferably set within the range of 0.85 to 0.95.

The duration of plasma production T₁ preferably includes a reaction time from the start to the end of a reaction between part of a component of the raw material gas and the reaction gas and a property-adjusting time for changing the degree of the property (at least one property selected from refractive index, dielectric strength, and dielectric constant) of a film formed by the reaction. Particularly, the property of the film can be changed by changing the property-adjusting time following the end of the reaction. As described above, in the present embodiment, a reaction between part of a component of the raw material gas and the reaction gas and adjustment of the property of a film'can be performed by plasma produced at a time. One atomic layer film or, at most, about two atomic layer films is/are formed by the reaction between part of a component of the raw material gas and the reaction gas, and therefore plasma is required to act on only the formed atomic layer film(s). For this reason, the duration of plasma production can be set to 100 milliseconds or shorter.

FIG. 3 is a graph illustrating how the property of a film to be formed changes according to the duration of plasma production T₁. The property of the film is refractive index as a representative example. Examples of the property of the film other than refractive index include dielectric strength and dielectric constant. The film has a higher refractive index when more densely formed. FIG. 3 illustrates, as an example, the data of refractive index obtained when aluminium oxide is formed on a silicon substrate at 200° C. by a film-forming method based on ALD using plasma. TMA gas and oxygen gas were used to form aluminium oxide. The area of the silicon substrate was about 300 cm², and input power was 500 W. A cycle including TMA gas supply, oxygen gas supply, and plasma production was repeated to form a film having a thickness of 0.1 μm.

At this time, the duration of plasma production T₁ was changed within the range of 5 milliseconds to 500 milliseconds, and the refractive index of a film formed at this time was measured with a spectroscopic ellipsometer. The refractive index of an aluminium oxide film formed by ALD is 1.63 to 1.65 when the film is sufficiently dense. As can be seen from FIG. 3, when the duration of plasma production T₁ is in the range of 1 millisecond or longer but 100 milliseconds or shorter, a film having a higher refractive index can be formed by increasing the duration of plasma production T₁.

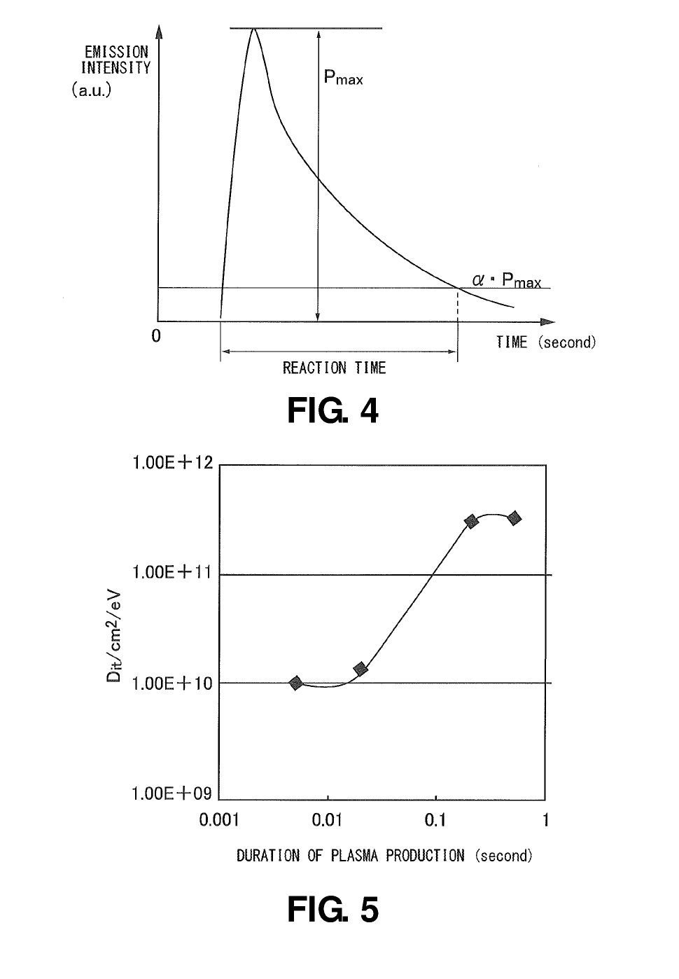

FIG. 4 is a graph illustrating an example of a temporal change in the emission intensity of hydrogen radicals formed by a reaction between part of a component of the raw material gas and the reaction gas, which is detected by a photo-detection sensor provided in the film-forming vessel 12 during plasma production. In this case, a reaction time from the start to the end of the reaction is the time from when emission intensity is detected with the photo-detection sensor until when the emission intensity reaches its maximum value Pₘₐₓ and is then diminished to a (a number larger than 0 but less than 1) times the maximum value Pₘₐₓ. The a is preferably, for example, 1/e (e is the base of natural logarithm). Such a reaction time from the start to the end of a reaction between part of a component of the raw material gas and the reaction gas with the use of plasma is roughly 0.5 millisecond to 2 milliseconds.

As illustrated in FIG. 3, when the duration of plasma production T₁ including such a reaction time is in the range of 1 millisecond or longer but 20 milliseconds or shorter, more specifically in the range of 2 milliseconds or longer but 20 milliseconds or shorter, the refractive index greatly changes according to the duration of plasma production T₁. Therefore, the duration of plasma production T₁ is preferably 1 millisecond or longer but 20 milliseconds or shorter, more preferably 2 milliseconds or longer but 20 milliseconds or shorter. On the other hand, when the duration of plasma production T₁ is longer than 100 milliseconds, the refractive index of the film is constant and is not changed according to the duration of plasma production T₁. As can be seen from the facts, when the duration of plasma production T₁ is in the range of 0.5 millisecond or longer but 100 milliseconds or shorter, more specifically in the range of 2 milliseconds or longer but 20 milliseconds or shorter, the property of the film can be changed by changing the duration of plasma production T₁. The duration of plasma production T₁ is preferably changed by, for example, the controller 20 or the power source control part 20a.

It is to be noted that power input to the upper electrode 14a is in the range of 15 to 3000 W so that input power per unit area determined by dividing input power by an area of the electrode (upper electrode 14a) of 300 cm² is in the range of 0.05 W/cm² to 10 W/cm².

FIG. 5 is a graph illustrating a change in the interface state density Dit of the aluminium oxide film formed on the silicon substrate in the example illustrated in FIG. 3 with respect to the duration of plasma production T₁. The substrate having the film formed thereon was subjected to heat treatment at 400° C. for 0.5 hours in a nitrogen gas atmosphere (under atmospheric pressure) before the measurement of interface state density Dit. The interface state density Dit is a well-known property, and increases when a substrate is subjected to bombardment with ions in plasma. Therefore, the interface state density Dit can give an indication of the degree of bombardment of a film with ions. A larger interface state density Dit means that a film has been more damaged by ions. As can be seen from FIG. 5, when the duration of plasma production T₁ is shorter, the interface state density Dit is smaller, that is, the substrate has not been damaged by plasma. Therefore, based on the data illustrated in FIGS. 3 and 5, the duration of plasma production T₁ is preferably set within the range of 20 milliseconds or shorter in order to efficiently control the property of the film without damage to the film caused by plasma. In order to prevent great damage to the film caused by plasma, the duration of plasma production T₁ is preferably set within the range of 2 milliseconds or longer but 15 milliseconds or shorter, more preferably within the range of 2 milliseconds or longer but 10 milliseconds or shorter.

For example, when the duration of plasma production T₁ is set to 10 milliseconds, a film that is relatively less dense and has a refractive index of about 1.60 can be formed. On the other hand, when the duration of plasma production T₁ is set to 20 milliseconds, a film that is relatively dense and has a refractive index of about 1.62 can be formed. Conventionally, a dense aluminium oxide film (film having a high refractive index) is formed by producing plasma using oxygen gas (by producing oxygen plasma) to form oxygen radicals and reacting the oxygen radicals with a component of TMA, and a less-dense aluminium oxide film (film having a low refractive index) is formed by reacting ozone gas with a component of TMA gas. Therefore, in a case where a less-dense film and a dense film are to be formed on one substrate as a lower layer and an upper layer, respectively, a film-forming device needs to be changed because a reaction gas to be used is different between when the film as a lower layer is formed and when the film as an upper layer is formed. A system that produces oxygen plasma and a system that provides ozone gas can be incorporated into one film-forming device, which however increases the cost of the film-forming device. On the other hand, the film-forming device according to the present embodiment can freely switch between forming a dense film and forming a less-dense film simply by adjusting the duration of plasma production T₁.

The film formed in the embodiment contains a metal component such as aluminium. On the other hand, the substrate on which a film is to be formed may be a plate having a composition not containing a metal component, such as aluminium. The substrate ma be a plate made of, for example, a resin. Alternatively, a glass substrate or a ceramic substrate may be used.

It is to be noted that when a dense film is formed so as to be in direct contact with a substrate, the film is likely to be peeled off from the substrate due to the tensile stress of the film. Further, the dense film is hard, and is therefore likely to be peeled off from the substrate when the substrate is bent. For these reasons, in order to ensure the adhesion of a film to a substrate, part of the film that is in contact with the substrate is preferably soft and less dense. Therefore, it is preferred that a less-dense film is formed on a substrate as a lower layer, and a dense film is formed as an upper layer on the less-dense film. In this case, the degree of denseness may be gradually increased from the lower layer toward the upper layer. For example, a film can be formed whose refractive index increases from its substrate side toward its uppermost layer side. The refractive index can be measured with a spectroscopic ellipsometer. In this case, the formed film is less likely to be peeled off even when the substrate is a flexible substrate that is highly deformable. In this case, the substrate on which a film is to be formed may be a plate (including a film) having a composition not containing a metal component contained in the film to be formed or a plate (including a film) made of, for example, a resin. Alternatively, the substrate may be a glass substrate or a ceramic substrate. Generally, a substrate on which a film is to be formed has, for example, a thermal expansion coefficient different from that of the film to be formed, but even when a film is formed on such a substrate, peeling-off of the formed film due to the difference in thermal expansion is less likely to occur as long as the film is formed so that its refractive index increases from its substrate side toward its uppermost layer side.

In order to form such a film, it is preferred that, as in the case of the present embodiment, the film-forming device 10 is used by which a film property can be controlled by adjusting the duration of plasma production T₁.

In the present embodiment, one cycle including supply of a raw material gas such as TMA gas, supply of a reaction gas, such as oxygen gas, performed after the supply of the raw material gas, and plasma production using the reaction gas by the plasma source such as the upper electrode 14a is repeated. At this time, it is preferred that the duration of plasma production Ti is controlled to be different between at least two cycles. This makes it possible to form a film having portions different in film property.

Particularly, during the repetition of the above cycle, the high-frequency power source 20 preferably controls the plasma source such as the upper electrode 14a so that the duration of plasma production T₁ of the first one cycle is shorter than that of the last one cycle. This makes it possible to form a film whose lower layer on its substrate side is less dense and whose upper layer is dense.

Further, during the repetition of the above cycle, the high-frequency power source 20 preferably controls power supplied to the upper electrode 14a so that the duration of plasma production T₁ increases as the number of repetitions of the cycle increases. This makes it possible to form a film whose degree of denseness gradually increases from its substrate-side lower layer toward its upper layer.

It is to be noted that in the present embodiment, plasma production using oxygen gas is performed once per cycle, but pulsed plasma may be produced, more than once, for a duration shorter than the duration of plasma production T₁. In this case, the cumulative total time of plasma production may be equal to the duration of plasma production T₁. That is, plasma production may be performed more than once in at least one cycle so that the total duration of plasma production performed more than once is in the range of 0.5 millisecond to 100 milliseconds.

It is to be noted that in the embodiment, TMA gas is used as an example of the raw material gas, but the raw material gas is not limited to TMA gas. For example, TEA (tetraethylammonium) gas or DMAOPr (dimethylaluminum isopropoxide) gas may also be used. Further, the film to be formed is not limited to aluminium oxide, and may be an oxide of Si, Mg, Ti, Cr, Fe, Ni, Cu, Zn, Ga, Ge, Y, Zr, In, Sn, Hf, or Ta. Further, the reaction gas is not limited to oxygen gas, and may be nitrogen gas, N₂O, NH₃, H₂, or H₂O.

The film-forming device and the film-forming method according to the present invention have been described above in detail, but the present invention is not limited to the above embodiment. It is obvious that various changes and modifications may be made without departing from the scope of the present invention.

### REFERENCE SIGNS LIST

10 film-forming device

12 film-forming vessel

12a projecting wall

14 Parallel plate electrode

14a upper electrode

14b lower electrode

16 gas supply unit

16a TMA source

16b N₂ source

16c O₂ source

17a, 17b, 17c valves

18 controller

18a, 18b, 18c pipes

20 high-frequency power source

20a power source control part

22 matching box

24 exhaust unit

26 conductance variable valve

28 exhaust pipe

30 susceptor

30a elevating shaft

30b elevating system

32 heater

1. A film-forming device for forming a film atomic layer by atomic layer with a use of a raw material gas and a reaction gas, the device comprising:
a film-forming vessel having a film-forming space in which a substrate is placed;
a raw material gas supply part configured to supply a raw material gas into the film-forming space to adsorb a component of the raw material gas onto the substrate;
a reaction gas supply part configured to supply a reaction gas into the film-forming space;
a plasma source that comprises an electrode configured to produce plasma using the reaction gas supplied into the film-forming space so that a film is formed on the substrate by a reaction between part of the component of the raw material gas adsorbed on the substrate and the reaction gas; and
a high-frequency power source configured to supply power to the electrode of the plasma source so that a duration of production of the plasma is in a range of 0.5 millisecond to 100 milliseconds and a density of the power input to the plasma source is in a range of 0.05 W/cm² to 10 W/cm², the duration of production of the plasma being set according to a degree of at least one property of a film to be formed selected from refractive index, dielectric strength, and dielectric constant.

2. The film-forming device according to claim 1, further comprising a first control part configured to determine, as a start point of production of the plasma, a time point when reflected power of power input to the plasma source crosses a value set within a range of 85 to 95% of the input power after the power is input.

3. The film-forming device according to claim 1, wherein the duration of production of the plasma includes a reaction time from start to end of a reaction between part of the component of the raw material gas and the reaction gas and a property-adjusting time for changing the property of a film formed by the reaction.

4. The film-forming device according to claim 1, further comprising a second control part configured to control operations of the raw material gas supply part and the reaction gas supply part to repeat a cycle including supply of a raw material gas performed by the raw material gas supply part, supply of a reaction gas performed by the reaction gas supply part after the supply of the raw material gas, and plasma production using the reaction gas performed by the plasma source, wherein during repetition of the cycle, the first control part is configured to change the duration of production of the plasma by the plasma source between at least two cycles.

5. The film-forming device according to claim 4, wherein the duration of production of the plasma of a first one cycle is shorter than the duration of production of the plasma of a last one cycle.

6. The film-forming device according to claim 5, wherein the duration of production of the plasma increases as a number of repetitions of the cycle increases.

7. The film-forming device according to claim 4, wherein production of the plasma is performed more than once in at least one cycle, and a total duration of plasma production performed more than once is in a range of 0.5 millisecond to 100 milliseconds.

8. The film-forming device according to claim 1, wherein the degree of the property has at least three different levels of the property.

9. A film-forming method for forming a film atomic layer by atomic layer with a use of a raw material gas and a reaction gas, the method comprising the steps of:
supplying a raw material gas into a film-forming space in which a substrate is placed to adsorb a component of the raw material gas onto the substrate;
supplying a reaction gas into the film-forming space; and
supplying power to an electrode of a plasma source to produce plasma in the film-forming space with a use of the reaction gas supplied into the film-forming space so that part of a component of the raw material gas adsorbed on the substrate reacts with the reaction gas to form a film on the substrate, a duration of production of the plasma being set within a range of 0.5 millisecond to 100 milliseconds according to a degree of at least one property of a film to be formed selected from refractive index, dielectric strength, and dielectric constant, and a density of power input to the plasma source being in a range of 0.05 W/cm² to 10 W/cm².

10. The film-forming method according to claim 9, wherein a time point when reflected power of power input to the plasma source to produce the plasma crosses a value set within a range of 85 to 95% of the input power after the power is input is determined as a start point of production of the plasma to determine an end point of input of the power to the plasma source.

11. The film-forming method according to claim 9, wherein the duration of production of the plasma includes a reaction time from start to end of a reaction between part of the component of the raw material gas and the reaction gas and a property-adjusting time for changing the property of a film formed by the reaction.

12. The film-forming method according to claim 9, wherein a cycle including supply of the raw material gas, supply of the reaction gas performed after the supply of the raw material gas, and plasma production using the reaction gas performed by the plasma source is repeated, and during repetition of the cycle, the duration of production of the plasma by the plasma source is different between at least two cycles.

13. The film-forming method according to claim 12, wherein during repetition of the cycle, the duration of production of the plasma of a first one cycle is shorter than the duration of production of the plasma of a last one cycle.

14. The film-forming method according to claim 13, wherein during repetition of the cycle, the duration of production of the plasma increases as a number of repetitions of the cycle increases.

15. The film-forming method according to claim 14, wherein the film has a refractive index increasing from its substrate side to its uppermost layer side.

16. The film-forming method according to claim 12, wherein production of the plasma is performed more than once in at least one cycle, and a total duration of plasma production performed more than once is in a range of 0.5 millisecond to 100 milliseconds.

17. The film-forming method according to claim 9, wherein the degree of the property has at least three different levels of the property.

18. The film-forming method according to claim 9, wherein the substrate is a flexible substrate.

19. The film-forming method according to claim 9, wherein the film contains a metal component, and the substrate is a plate having a composition not containing the metal component.
